(19) United States
(12) Patent Application Publication
(10) Pub. No.: US 2024/0294829 A1
(43) Pub. Date: Sep. 5, 2024

(54) ETCHING GAS AND ETCHING METHOD USING THE SAME

(71) Applicant: SAMSUNG ELECTRONICS CO., LTD., Suwon-si (KR)

(72) Inventors: Yeonock HAN, Suwon-si (KR); Jinkoo PARK, Suwon-si (KR); Do Hoon KIM, Suwon-si (KR); Hoin KANG, Suwon-si (KR); Bongsuk KIM, Suwon-si (KR); Kyungeun LEE, Suwon-si (KR); Wonwoong CHUNG, Suwon-si (KR)

(73) Assignee: Foosung Co., Ltd., Seongnam-si (KR)

(21) Appl. No.: 18/376,034

(22) Filed: Oct. 3, 2023

(30) Foreign Application Priority Data
Mar. 3, 2023 (KR) 10-2023-0028504

(51) Int. Cl. C09K 13/00; H01L 21/311

(52) U.S. Cl. CPC C09K 13/00; H01L 21/31116

(57) ABSTRACT

An etching gas and an etching method, the etching gas includes hydrogen gas; a halogen gas; a first gas; and a second gas, wherein the first gas includes a phosphorus atom, and the second gas includes a carbon atom and two or more halogen atoms that are different from each other.

### CROSS-REFERENCE TO RELATED APPLICATION

This application claims priority to and the benefit of Korean Patent Application No. 10-2023-0028504 filed in the Korean Intellectual Property Office on Mar. 3, 2023, the entire contents of which are incorporated herein by reference.

### BACKGROUND

### 1. Field

Embodiments relates to an etching gas and an etching method using the same.

### 2. Description of the Related Art

One type of semiconductor device may include a NAND type flash memory device having a three-dimensional structure. In the manufacture of a NAND flash memory device having a three-dimensional structure, an etching process may be performed in which a multilayer film formed by alternately providing a silicon oxide layer and a silicon nitride layer is etched to form a deep hole in the multilayer film.

The multilayer film may be etched by exposing the multilayer film to plasma of a processing gas.

### SUMMARY

The embodiments may be realized by providing an etching gas including hydrogen gas; a halogen gas; a first gas; and a second gas, wherein the first gas includes a phosphorus atom, and the second gas includes a carbon atom and two or more halogen atoms that are different from each other.

The embodiments may be realized by providing an etching method including providing a substrate in a chamber, the substrate including a silicon-containing layer and another layer thereon; and etching the other layer by generating plasma from an etching gas in the chamber, wherein the other layer includes an oxide layer and a nitride layer such that a region of the other layer including both the oxide layer and the nitride layer is a first region, and a region of the other layer not including the nitride layer is a second region, and the etching gas includes a first gas containing a phosphorus atom and a second gas containing a carbon atom and two or more halogen atoms different from each other.

The embodiments may be realized by providing an etching method including providing a substrate in a chamber, the substrate including a silicon-containing layer and another layer thereon; depositing a mask on the other layer; and etching the mask and the other layer by generating plasma from an etching gas in the chamber, wherein the other layer includes an oxide layer and a nitride layer such that a region of the other layer including both the oxide layer and the nitride layer is a first region, and a region of the other layer not including the nitride layer is a second region, and the etching gas includes a first gas containing a phosphorus atom and a second gas containing a carbon atom and two or more halogen atoms different from each other.

### BRIEF DESCRIPTION OF THE DRAWINGS

Features will be apparent to those of skill in the art by describing in detail exemplary embodiments with reference to the attached drawings in which:

FIGS. 1 and 2 are diagrams (cross-sectional views of memory device) illustrating etching with a comparative etching gas.

FIG. 3 is a graph showing etch rates for each layer when a flow rate of first gas, phosphorus pentafluoride, is constant, and at the same time, a flow rate of second gas, C₂F₃Cl, is gradually increased.

FIG. 4 is a graph showing the etch rates for each layer when the flow rate of the second gas, C₂F₃Cl, is constant, and at the same time, the flow rate of the first gas, phosphorus pentafluoride, is gradually increased.

FIGS. 5 and 6 are diagrams (cross-sectional views of memory device) illustrating etching with etching gas according to an embodiment.

### DETAILED DESCRIPTION

According to an embodiment, the etching gas may include a hydrogen gas, a halogen gas, a first gas, and a second gas. In an implementation, the first gas may include a phosphorus atom (e.g., may be a compound including a phosphorous atom therein), and the second gas may include a carbon atom and two or more halogen atoms that are different from each other (e.g., may be a compound including a carbon atom and two or more different halogen atoms).

The hydrogen gas may mean a H₂ gas. The halogen gas may mean gases composed only of halogen atoms, e.g., F₂, Cl₂, Br₂, or I₂. As used herein, the term “or” is not an exclusive term, e.g., “A or B” would include A, B, or A and B.

The first gas and the second gas may be different from each other, and the first gas and the second gas may also be different from the hydrogen gas and the halogen gas, respectively.

In an implementation, in order to increase the etch rate for the oxide layer in the low-temperature environment, the first gas containing a phosphorus (P) atom may be included. The etch rate for the oxide layer may be improved in the low-temperature environment due to the presence of the first gas containing the phosphorus atom.

In an implementation, the first gas may further include a halogen atom, an oxygen atom, or a combination thereof, in addition to the phosphorus atom.

In an implementation, the first gas may be represented by Chemical Formula 1 or Chemical Formula 2 below.

PX₅ [Chemical Formula 1]

P(═O)X₃ [Chemical Formula 2]

In Formula 1 and Formula 2, X may be a halogen atom.

In an implementation, the first gas may include phosphorus pentafluoride.

In an implementation, the first gas may include phosphorus oxychloride.

In an implementation, the second gas may include a fluorine atom and a chlorine atom.

The second gas may include a carbon atom and two or more halogen atoms that are different from each other. The second gas may help reduce the etch rate for the polysilicon through the formation of a silicon polymer by including the carbon atom as a carbon source (e.g., to help improve the selectivity for the polysilicon). In an implementation, the second gas may help preserve the etch rates for the nitride layer and the oxide layer by including two or more different halogen atoms.

The two or more types of halogen atoms may be two or more different halogen atoms.

Among the two or more halogen atoms, a chlorine atom may be a main etching species of silicon, and relatively fewer chlorine atoms than other halogen atoms may be advantageous in terms of improving the selectivity for the polysilicon.

In an implementation, the second gas may include a fluorine atom and a chlorine atom. In an implementation, a number of chlorine atoms in the second gas (e.g., in each molecule of the second gas) may be smaller than a number of fluorine atoms in the second gas. In an implementation, the number of chlorine atoms in the second gas may be smaller than a number of carbon atoms in the second gas. In an implementation, the second gas may help improve the selectivity for the polysilicon.

The etching gas according to an embodiment may help increase the selectivity for the polysilicon while increasing the etch rate for the oxide layer in a low-temperature environment by controlling flow rates of the first gas and the second gas.

In an implementation, the flow rate of the first gas in the etching gas may be 5 times or less than that of the second gas in the etching gas. In an implementation, the flow rates of other gases (constituting the etching gas) excluding the first gas and the second gas may be held constant. When the flow rates of the first gas and the second gas are controlled as described above, a difference in etch rate between the oxide layer and the nitride layer, respectively, may be reduced, a difference in etch rate between the oxide layer and the polysilicon layer may be great, and a difference in etch rate between the nitride layer and the polysilicon layer may also be great, thereby increasing the selectivity for the polysilicon layer.

In an implementation, the flow rate of the hydrogen gas in the etching gas may be larger than that of each of the halogen gas, the first gas, and the second gas.

In an implementation, the etching gas may further include other types of gases in addition to the above-described gases.

In an implementation, the etching gas may further include a gas containing a carbon atom and one type of halogen atom.

In an implementation, the etching gas may further include a halogenated hydrogen gas.

In an implementation, when the etching gas further includes the gas containing a carbon atom and one type of halogen atom and the halogenated hydrogen gas, the gas containing a carbon atom and one type of halogen atom may be supplied at a larger flow rate than the halogenated hydrogen gas.

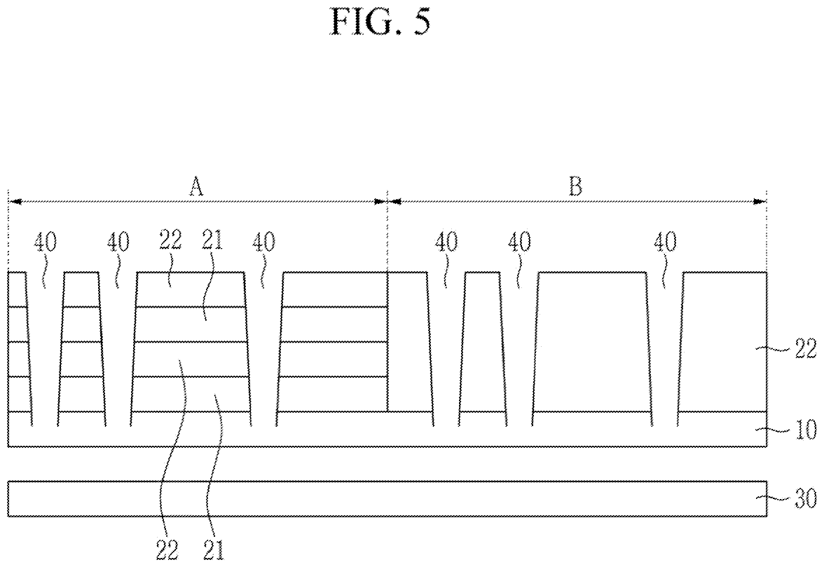

Referring to FIG. 5, the etching method according to an embodiment may include providing a substrate in a chamber, the substrate including a silicon-containing layer (which is the stop layer 10) and another layer thereon; and etching the other layer by generating plasma from an etching gas in the chamber. The other layer may include an oxide layer 22 and a nitride layer 21. In an implementation, a region including both the oxide layer and the nitride layer may be a first region A, and a region not including the nitride layer may be a second region B. The etching gas may include the first gas containing a phosphorus atom and the second gas containing a carbon atom and two or more halogen atoms different from each other.

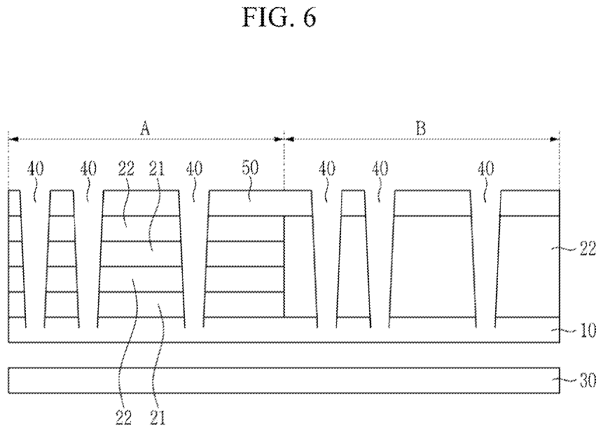

Referring to FIG. 6, the etching method according to an embodiment may include providing a substrate in a chamber, the substrate including a silicon-containing layer (which is the stop layer 10) and another layer on the substrate; depositing a mask 50 on the other layer; and etching the mask 50 and the other layer by generating plasma from an etching gas in the chamber. The layer may include an oxide layer 22 and a nitride layer 21. A region including both the oxide layer and the nitride layer may be a first region A, and a region not including the nitride layer may be a second region B. The etching gas may include the first gas containing a phosphorus atom and the second gas containing a carbon atom and two or more halogen atoms different from each other.

The first region A may be a multilayer film. The multilayer film may be configured by alternately providing a silicon oxide layer 22 and a silicon nitride layer 21. A thickness of the silicon oxide layer 22 may be, e.g., 5 nm to 50 nm, and a thickness of the silicon nitride layer 21 may be, e.g., 10 nm to 75 nm. In an implementation, the silicon oxide layer 22 and the silicon nitride layer 21 may be stacked in a total of 24 or more layers.

The second region B may include the silicon oxide layer 22 in a single layer. A thickness of the second region B may be substantially the same as that of the first region A.

Referring to FIG. 6, the mask 50 may be on the first area A and the second area B. The mask 50 may have a pattern for forming a space, e.g., the channel hole 40, on the first region A and the second region B. The mask 50 may be made of, e.g., amorphous carbon. In an implementation, the mask 50 may include an organic polymer, e.g., polysilicon, or may be made of polysilicon. When the mask is made of polysilicon, it may be more robust than when the mask is made of amorphous carbon, and it is possible to significantly reduce defects such as a bowing profile.

The etching method according to an embodiment may be performed at a low temperature of, e.g., less than 0°° C. When etching is performed at a low temperature of less than 0° C., the etch rates for the oxide layer and the nitride layer may increase, but by-products generated by the etching may not be volatilized smoothly, so the by-products may be deposited on the side wall, bottom, or the like of the channel hole. As a result, it could become difficult for the etching to proceed linearly in a depth direction. In addition, when the etching is performed with a phosphorus-containing gas, the generation of the by-products could be further promoted by etching, and thus, it could be easy to further hinder the etching from proceeding linearly in the depth direction. The etching gas according to an embodiment may include the second gas including the carbon atom and two or more different halogen atoms in addition to the phosphorus-containing gas, and thus, the above-described issues may be addressed. In an implementation, the etching gas according to an embodiment may have a composition optimized for an etching method according to an embodiment performed at a low temperature.

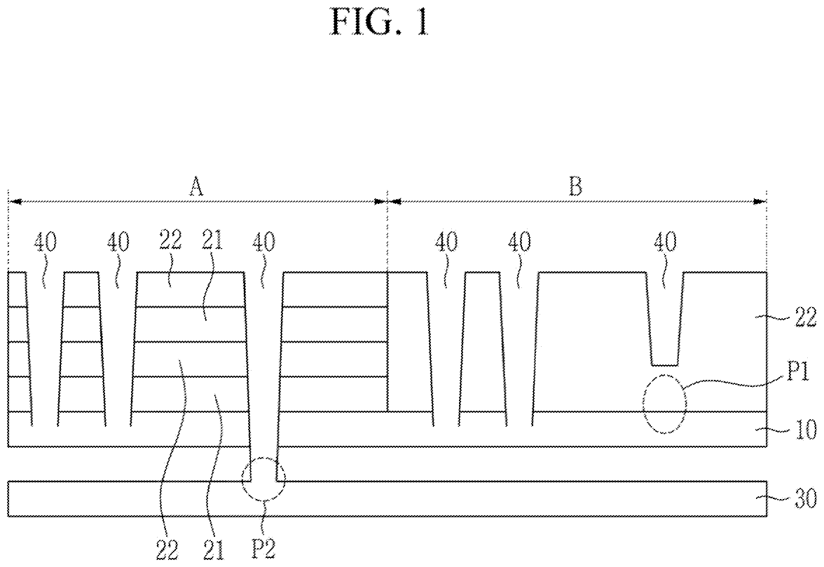

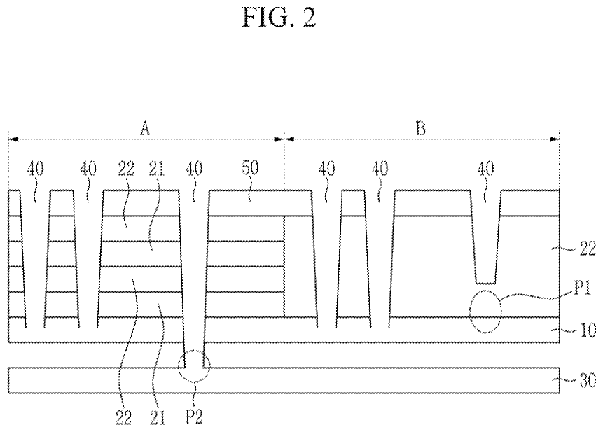

Referring to FIGS. 1 and 2, compared to FIGS. 5 and 6, it may be be seen that the stacked structure constituting the memory device is the same, but the position of the channel hole 40 may be different. This may be because the etching gas used in FIGS. 1 and 2 may be different from the etching gas used in FIGS. 5 and 6. The etching gas used in FIGS. 1 and 2 may include the hydrogen gas, the halogen gas, the gas containing the carbon atom and one kind of halogen atom, and a halogenated hydrogen gas, whereas the etching gas used in FIGS. 5 and 6 may include the hydrogen gas, the halogen gas, the first gas, and the second gas. The etching gas used in FIGS. 1 and 2 may not include the first gas and the second gas, and the channel hole 40 may not progress linearly in the depth direction due to the decrease in the etch rate for the oxide layer 22 in the second region B. In addition, the selectivity for the polysilicon, which is the stop layer 10, may be lowered in the first region A, and all of the lower metal wirings 30 may be exposed therethrough.

The etching gas may be the same as described above.

Hereinafter, various experiments performed to evaluate an etching method using an etching gas according to an embodiment will be described. Experiments described below do not limit the present disclosure.

### Experiment 1

The composition of the etching gas was as follows.

100 sccm of PF₅, 150 to 190 sccm of H₂, 90 to 130 sccm of CH₂F₂, 20 to 60 sccm of HBr, 20 to 60 sccm of Cl₂, 0 to 100 sccm of C₂F₃Cl (chlorotrifluoroethylene)

Specifically, the flow rate of PFs was set to 100 sccm and the flow rate of chlorotrifluoroethylene was set to 0 to 100 sccm to split into the silicon oxide layer, the silicon nitride layer, the amorphous carbon layer, and the polysilicon layer, respectively.

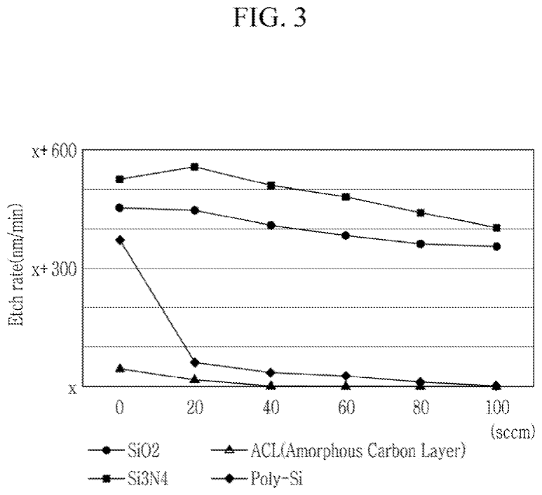

Referring to FIG. 3, it may be seen that the difference in etch rates for each oxide layer and the nitride layer decreased as the flow rate of chlorotrifluoroethylene increased while PFs is present, and the etch rate for the polysilicon gradually decreased as the flow rate of chlorotrifluoroethylene increased. It may be clearly seen that, in the region where the flow rate of PFs was 5 times or less that of chlorotrifluoroethylene, the difference in etch rates for each oxide layer and nitride layer decreased, and the etch rate for the polysilicon was lowered.

### Experiment 2

The composition of the etching gas was as follows.

0 to 120 sccm of PF₅, 150 to 190 sccm of H₂, 90 to 130 sccm of CH₂F₂, 20 to 60 sccm of HBr, 20 to 60 sccm of Cl₂, 20 sccm of C₂F₃Cl (chlorotrifluoroethylene)

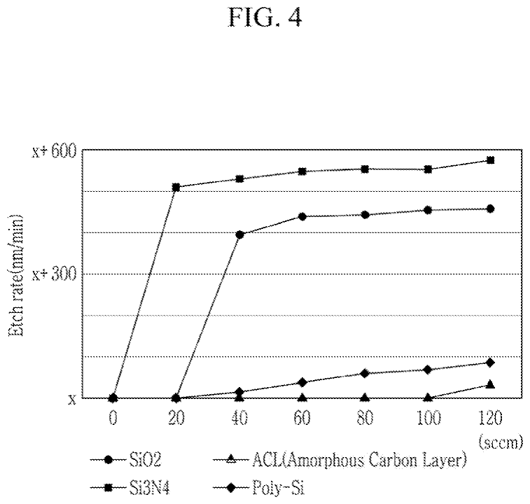

By setting the flow rate of PF₅ to 0 to 120 sccm while the flow rate of chlorotrifluoroethylene was set to 20 sccm, the results of splitting into the silicon oxide layer, the silicon nitride layer, the amorphous carbon layer, and the polysilicon layer, respectively, are illustrated in FIG. 4. Referring to FIG. 4, it may be seen that as the flow rate of PFs increased, the difference in etch rates for each oxide layer and nitride layer, respectively, decreased. Although the etch rate for the polysilicon gradually increased as the flow rate of PFs increased, the degree of increase was not large and may be ignored. It may be clearly seen that, as the difference in etch rates for each oxide layer and nitride layer increased again from the region where the flow rate of PF₅ was less than 5 times that of chlorotrifluoroethylene, the etch rate for the polysilicon also increased. It may be clearly seen that the region where the flow rate of PF₅ was 5 times or less that of chlorotrifluoroethylene is the region where the etch rate for the polysilicon may be minimized while narrowing the difference in etch rates for each oxide layer and nitride layer.

Based on the results of Experiments 1 and 2, it may be seen that the HARC process in the low-temperature environment may overcome the limitations of a merged etching process when PFs and chlorotrifluoroethylene are applied simultaneously (e.g., that a channel hole may not reach polysilicon due to decrease in etch rate in the second region during the low-temperature etching process and that selectivity for polysilicon may be low, and thus, the channel hole could penetrate through polysilicon and even a lower metal wiring could be exposed, during low-temperature etching process).

By way of summation and review, a multilayer film to be etched may have a first region having a multilayer film constituted by alternately providing a silicon oxide layer and a silicon nitride layer, and a second region having a silicon oxide layer of a single layer. A space like a channel hole may be formed in both the first region and the second region by etching such a multilayer film.

In order to simplify a process of a NAND flash memory device having a three-dimensional structure, technology using a high aspect ratio contact (HARC) process is continuously being developed, and as a low-temperature etching process applied from channel hole (Ch. Hole) etching is merged with the HARC process, there is a strong demand for development of an etching process with which the HARC process is merged in a low-temperature environment. As the combined etching of the HARC process proceeds in the low-temperature environment, some limitations have been revealed, and a different etching gas may be used.

Among the limitations of the etching process with which the HARC process is merged in the current low-temperature environment, first, a channel hole 40 in the oxide layer 22 of the second region B may not reach the substrate having the silicon-containing layer, which is a stop layer 10, due to a difference in etch rate between a first region A in which a (silicon) nitride layer 21 and a (silicon) oxide layer 22 are alternately provided and a second region B in which the (silicon) nitride layer is not provided and the (silicon) oxide layer 22 is provided (see P1 in FIGS. 1 and 2). The etch rate of the oxide layer could be lowered in the low-temperature environment, the oxide layer of the second region could be relatively less etched when etching is performed simultaneously with the first region, so this phenomenon occurs.

In addition, a polysilicon (Poly Si) layer could be used as the stop layer 10 so that the etching could be stopped in the channel hole (Ch. hole) 40, and in a low-temperature process, the selectivity for the polysilicon could be lowered, so the polysilicon layer may not serve as the stop layer, and even a lower metal wiring 30 could be exposed (see P2 in FIGS. 1 and 2).

An etching gas according to an embodiment may address the above two limitations, may be capable of increasing an etch rate for an oxide layer in a low-temperature environment, and at the same time, may have selectivity for polysilicon (lowering the etch rate).

One or more embodiments may provide an etching gas and an etching method using the same capable of increasing an etch rate for an oxide layer in a low-temperature environment and at the same time securing selectivity for a silicon-containing layer.

One or more embodiments may provide an etching gas and an etching method using the same capable of preventing further etching after a channel hole reaches a stop layer by suppressing a decrease in selectivity for the stop layer in a region where a silicon oxide layer and a silicon nitride layer are alternately provided simultaneously with suppressing a decrease in an etch rate for the region having the silicon oxide layer when etching both the region where the silicon oxide layer and the silicon nitride layer are alternately provided and the region having the silicon oxide layer in a low-temperature environment.

When etching is performed using an etching gas according to an embodiment, it is possible to overcome a difference in etch rates for a silicon nitride layer and a silicon oxide layer, and at the same time, prevent a lower metal wiring from being exposed by securing selectivity for polysilicon.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated.

Accordingly, it will be understood by those of skill in the art that various changes in form and details may be made without departing from the spirit and scope of the present invention as set forth in the following claims.

What is claimed is:

1. An etching gas, comprising:
hydrogen gas;
a halogen gas;
a first gas; and
a second gas,
wherein:
the first gas includes a phosphorus atom, and
the second gas includes a carbon atom and two or more halogen atoms that are different from each other.

2. The etching gas as claimed in claim 1, wherein the first gas further includes a halogen atom, an oxygen atom, or a combination thereof.

3. The etching gas as claimed in claim 1, wherein the first gas includes phosphorus pentafluoride.

4. The etching gas as claimed in claim 1, wherein the second gas includes a fluorine atom and a chlorine atom.

5. The etching gas as claimed in claim 4, wherein a number of chlorine atoms in each molecule of the second gas is smaller than a number of fluorine atoms in each molecule of the second gas.

6. The etching gas as claimed in claim 4, wherein a number of chlorine atoms in each molecule of the second gas is smaller than a number of carbon atoms in each molecule of the second gas.

7. The etching gas as claimed in claim 1, wherein the second gas includes chlorotrifluoroethylene.

8. The etching gas as claimed in claim 1, wherein the first gas includes phosphorus oxychloride.

9. The etching gas as claimed in claim 1, wherein the etching gas further includes a gas containing a carbon atom and one type of halogen atom.

10. The etching gas as claimed in claim 1, wherein the etching gas further includes a halogenated hydrogen gas.

11. An etching method, comprising:
providing a substrate in a chamber, the substrate including a silicon-containing layer and another layer thereon; and
etching the other layer by generating plasma from an etching gas in the chamber,
wherein:
the other layer includes an oxide layer and a nitride layer such that a region of the other layer including both the oxide layer and the nitride layer is a first region, and a region of the other layer not including the nitride layer is a second region, and
the etching gas includes a first gas containing a phosphorus atom and a second gas containing a carbon atom and two or more halogen atoms different from each other.

12. The etching method as claimed in claim 11, wherein etching the other layer is performed at a temperature below 0° C.

13. The etching method as claimed in claim 11, wherein the first gas includes phosphorus pentafluoride.

14. The etching method as claimed in claim 11, wherein:
the second gas includes a fluorine atom and a chlorine atom,
a number of chlorine atoms in each molecule of the second gas is smaller than a number of fluorine atoms in each molecule of the second gas, and
the number of chlorine atoms in each molecule of the second gas is smaller than a number of carbon atoms in each molecule of the second gas.

15. The etching method as claimed in claim 11, wherein the etching gas is provided to the chamber such that a flow rate of the first gas in the etching gas is 5 times or less than a flow rate of the second gas in the etching gas.

16. An etching method, comprising:
providing a substrate in a chamber, the substrate including a silicon-containing layer and another layer thereon;
depositing a mask on the other layer; and
etching the mask and the other layer by generating plasma from an etching gas in the chamber,
wherein:
the other layer includes an oxide layer and a nitride layer such that a region of the other layer including both the oxide layer and the nitride layer is a first region, and a region of the other layer not including the nitride layer is a second region, and
the etching gas includes a first gas containing a phosphorus atom and a second gas containing a carbon atom and two or more halogen atoms different from each other.

17. The etching method as claimed in claim 16, wherein etching the mask and the other layer is performed at a temperature below 0° C.

18. The etching method as claimed in claim 16, wherein the mask includes polysilicon.

19. The etching method as claimed in claim 16, wherein:
the first gas includes phosphorus pentafluoride,
the second gas includes a fluorine atom and a chlorine atom,
a number of chlorine atoms in each molecule of the second gas is smaller than a number of fluorine atoms in each molecule of the second gas, and
the number of chlorine atoms in each molecule of the second gas is smaller than a number of carbon atoms in each molecule of the second gas.

20. The etching method as claimed in claim 16, wherein the etching gas is provided to the chamber such that a flow rate of the first gas in the etching gas is 5 times or less than a flow rate of the second gas in the etching gas.
